(19) United States
(12) Patent Application Publication
(10) Pub. No.: US 2014/0009898 A1
(43) Pub. Date: Jan. 9, 2014

(54) INTERPOSER SUBSTRATE, ELECTRONIC DEVICE PACKAGE, AND ELECTRONIC COMPONENT

(71) Applicant: Fujikura Ltd, Tokyo (JP)

(72) Inventor: Satoshi YAMAMOTO, Sakura-shi (JP)

(73) Assignee: Fujikura Ltd, Tokyo (JP)

(21) Appl. No.: 14/010,631

(22) Filed: Aug. 27, 2013

Related U.S. Application Data
(63) Continuation of application No. PCT/JP2012/062139, filed on May 11, 2012.

(30) Foreign Application Priority Data
May 12, 2011 (JP) 2011-107581

(51) Int. Cl. H05K 1/11

(52) U.S. Cl. CPC H05K 1/116
USPC 361/760; 174/266; 174/252

(57) ABSTRACT

An interposer substrate of the invention includes: a single substrate having a first main surface and a second main surface; a plurality of through-hole interconnections having at least a first portion formed so as to extend in a direction different from the thickness direction of the substrate, a second portion constituting one of end portions of a through-hole interconnection, and a third portion constituting the other of the end portions of the through-hole interconnection, the through-hole interconnections being provided inside the substrate so as to connect the first main surface to the second main surface, wherein the second portion is substantially perpendicular to the first main surface and is exposed to the first main surface, the third portion is substantially perpendicular to the second main surface and is exposed to the second main surface, and lengths of the through-hole interconnections are the same as each other.

### CROSS REFERENCE TO RELATED APPLICATIONS

This application is a continuation application based on a PCT Patent Application No. PCT/JP2012/062139, filed May 11, 2012, whose priority is claimed on Japanese Patent Application No. 2011-107581 filed on May 12, 2011, the content of which is hereby incorporated by reference.

### BACKGROUND OF THE INVENTION

1. Field of the Invention

The present invention relates to an interposer substrate, an electronic device package using this, and an electronic component, which are provided with through-hole interconnections realizing a SiP (system in package) in which a high-density package such as an integrated circuit device, an optical device, a MEMS device, or the like or such devices are systemized in a single package.

2. Description of the Related Art

In recent years, with the higher performance of electronic devices such as portable telephones or the like, higher speed and higher performance are required for electronic devices or the like used therein.

In order to achieve this, technological development is necessary for realizing not only a higher-speed and higher-performance device but also a higher-speed and higher-performance device package.

As a technique of high-density packaging, a SiP is proposed which uses a three-dimensional packaging technique of stacking and packaging chips by use of microscopic through-hole interconnections or uses an interposer substrate in which through-hole interconnections are formed.

Formation techniques of through-hole interconnections or an interposer substrate used for realizing a SiP have been actively researched and developed.

An interposer substrate, in which a through-hole interconnection is formed so as to be inclined to the direction perpendicular to a main surface of a substrate, is disclosed in, for example, Japanese Unexamined Patent Application, First Publication No. 2003-347502.

By applying the above-described forming technique of the through-hole interconnection, an interposer substrate can be obtained in which electrodes formed at different pitches on a top face and a back face of the substrate are connected to each other with through-hole interconnections.

However, there is a technical problem in the case of realizing higher-density three-dimensional packaging in the above-described interposer substrate.

For example, since a through-hole interconnection disclosed in Japanese Unexamined Patent Application, First Publication No. 2003-347502 is a through-hole interconnection extending in a straight line, positional limitation of the through-hole interconnection may occur.

In the case where, for example, a device is formed inside a substrate, it is necessary to form the through-hole interconnection so as to avoid the device.

In the interposer substrate in which the through-hole interconnection extending as straight as an arrow is formed, it is difficult to solve the foregoing problem.

Additionally, since a through-hole interconnection disclosed in Japanese Unexamined Patent Application, First Publication No. 2003-347502 is a through-hole interconnection extending in a straight line, and since the layout or pitches of the terminals are different from each other for each device depending on the kinds of devices mounted onto a top face and a back face of the interposer substrate, there is a significant difference in the lengths of through-hole interconnections to be manufactured.

Here, FIGS. 12 and 13 are views schematically showing a configuration example of an interposer substrate which is manufactured by applying Japanese Unexamined Patent Application, First Publication No. 2003-347502.

Here, FIG. 12 is a plan view illustrating a state where a plurality of terminal groups are arranged on the surface of a conventional interposer substrate.

Moreover, FIG. 13 is a cross-sectional view taken along the line M7-M7 shown in FIG. 12.

As a structure, it is thought that, for example, a plurality of terminals 130A, 130B, and 130C arranged at equal distance on the first main surface 110a of the substrate 110 are electrically connected to a plurality of terminals 130A′, 130B′, and 130C′ arranged at equal distance on the second main surface 110b of the substrate 110 through the through-hole interconnections 120A, 120B, and 120C, respectively, so that the terminal numbers thereof correspond to each other as shown in FIGS. 12 and 13.

Specifically, the terminals 130A′, 130B′, and 130C′ are arranged on the second main surface 110b of the substrate 110 with the same layout as that of the terminals 130A, 130B, and 130C, and the positions of the terminals 130A′, 130B′, and 130C′ on the second main surface 110b are different from the positions of the terminals 130A, 130B, and 130C in the X direction.

Here, the distance between the adjacent through-hole interconnections (between the edges) is constant and represented as P1 on the first main surface 110a, and is constant and represented as P2 on the second main surface 110b. Relationship of P1<P2 is satisfied.

At this time, it is apparent from FIG. 13 that the length of the through-hole interconnections between the terminals provided on the first main surface 110a is different from that of the second main surface 110b.

If the lengths of the through-hole interconnections are varied as mentioned above, there is variations in interconnection resistances of the through-hole interconnections, and it is difficult to control a voltage in signal transmission.

In addition, in a case of high-speed signal transmission from one end to the other end of the through-hole interconnections, there is a concern that variations in the wiring delay of the through-hole interconnections occurs depending on variations in the lengths of the through-hole interconnections.

Consequently, transmission of signals through the through-hole interconnections with synchronization becomes difficult.

Under circumstances as described above, there are problems in that performance of the interposer substrate degrades or performance of the electronic device using the interposer substrate degrades.

### SUMMARY OF THE INVENTION

The invention was conceived in view of the above-described circumstances and has an object thereof to provide an interposer substrate, an electronic device package, and an electronic component which reduce the interconnection resistance of a through-hole interconnection or difference in the wiring delay (variations).

In order to achieve the object, an interposer substrate of a first aspect of the invention includes: a single substrate having a first main surface (one of the main surfaces) and a second main surface (the other of the main surfaces); a plurality of through-hole interconnections having at least a first portion formed so as to extend in a direction different from the thickness direction of the substrate, a second portion constituting one of end portions of a through-hole interconnection, and a third portion constituting the other of the end portions of the through-hole interconnection, the through-hole interconnections being provided inside the substrate so as to connect the first main surface to the second main surface, wherein the second portion is substantially perpendicular to the first main surface and is exposed to the first main surface, the third portion is substantially perpendicular to the second main surface and is exposed to the second main surface, and lengths of the through-hole interconnections are the same as each other.

In the interposer substrate of the first aspect of the invention, it is preferable that a longitudinal direction of the first portion be substantially parallel to a main surface of the substrate.

According to the interposer substrate of the first aspect of the invention, the lengths of the through-hole interconnections are the same as each other.

Consequently, difference (variations) in the interconnection resistance values which is caused by difference in the lengths of the wirings in the through-hole interconnections eases.

Furthermore, it is possible to reduce variations in the wiring delay in case of transmitting signal from one end to the other end of the through-hole interconnections.

In addition, since the second portion and the third portion extend substantially perpendicular to a first main surface and a second main surface, respectively, even where the thickness of the substrate varies, the overall length of each through-hole interconnection (the total of the length of the first portion, the length of the second portion, and the length of the third portion) does not vary.

For this reason, the interconnection resistance values and the variations in the wiring delay of a plurality of through-hole interconnections does not vary.

As a result, the invention can realize an interposer substrate with excellent transmission characteristics.

In the interposer substrate of the first aspect of the invention, it is preferable that a longitudinal direction of the first portion be oblique to a main surface of the substrate.

According to such interposer substrate, the length of the through-hole interconnection connecting two predetermined surfaces of the substrate is shortened, contributing to a reduction in an interconnection resistance value.

It is preferable that the interposer substrate of the first aspect of the invention further include: a pad provided on the first main surface so as to be electrically connected to the second portion constituting the through-hole interconnection; and a pad provided on the second main surface so as to be electrically connected to the third portion constituting the through-hole interconnection.

When a device is mounted onto both faces of the interposer substrate, electrodes of the device are electrically connected to the pads without front wirings interposed therebetween.

Because of this, the through-hole interconnections can be directly connected to the device, even in cases where a downsized device in which the electrodes are densely arranged with any layout is used, it is possible to easily connect the downsized device to the interposer substrate.

In the interposer substrate of the first aspect of the invention, it is preferable that the substrate include a cooling unit cooling the substrate.

Therefore, even in cases where a device having a large amount of heat generation is packaged into the interposer substrate, since the cooling unit can effectively cool the device, increases in temperature of the entire package is reduced, and the performance of the device can be maintained.

An electronic device package of a second aspect of the invention includes: the interposer substrate of the aforementioned first aspect and an electronic device mounted onto at least one of the first main surface and the second main surface of the interposer substrate.

As a result, the invention is to contribute to the provision of an electronic device package with excellent transmission characteristics.

In the electronic device package of the second aspect of the invention, it is preferable that at least one end portion of the second portion and the third portion be located at a position facing a terminal of the electronic device and be electrically connected to the terminal of the electronic device.

When a device is mounted onto both faces of the interposer substrate, an electrode of the device is electrically connected to at least one of the end portion of the second portion and the end portion of the third portion without front wirings interposed therebetween.

Accordingly, even in cases where a downsized device in which the electrodes are densely arranged with any layout is used, it is possible to easily connect the downsized device to the interposer substrate.

An electronic component of a third aspect of the invention includes the electronic device package of the aforementioned second aspect.

As a result, the invention is to contribute to the provision of an electronic component with excellent signal transmission therein.

### Effects of the Invention

According to the invention, since the lengths of the through-hole interconnections are substantially the same as each other, it is possible to reduce the interconnection resistances of the through-hole interconnections or differences in the wiring delay (variations).

For this reason, it is possible to provide an interposer substrate, an electronic device package, and an electronic component which have excellent signal transmission characteristics.

### BRIEF DESCRIPTION OF THE DRAWINGS

FIG. 1 is a plan view schematically showing an interposer substrate of a first embodiment of the invention.

FIG. 2 is a cross-sectional view taken along the line M1-M1 shown in FIG. 1.

FIG. 3 is a cross-sectional view schematically showing the interposer substrate of the first embodiment of the invention.

FIG. 4 is a cross-sectional view schematically showing the interposer substrate of the first embodiment of the invention.

FIG. 5 is a cross-sectional view schematically showing an interposer substrate of a modified example of the first embodiment of the invention.

FIG. 6A is a plan view schematically showing an interposer substrate of a second embodiment of the invention.

FIG. 6B schematically shows the interposer substrate of the second embodiment of the invention and is a cross-sectional view taken along the line M2-M2 shown in FIG. 6A.

FIG. 7A is a plan view schematically showing an interposer substrate of a third embodiment of the invention.

FIG. 7B schematically shows the interposer substrate of the third embodiment of the invention and is a cross-sectional view taken along the line M3-M3 shown in FIG. 7A.

FIG. 7C schematically shows the interposer substrate of the third embodiment of the invention and is a cross-sectional view taken along the line N-N shown in FIG. 7A.

FIG. 8A is a plan view schematically showing an interposer substrate of a fourth embodiment of the invention.

FIG. 8B schematically shows the interposer substrate of the fourth embodiment of the invention and is a cross-sectional view taken along the line M4-M4 shown in FIG. 8A.

FIG. 8C schematically shows the interposer substrate of the fourth embodiment of the invention and is a cross-sectional view taken along the line M5-M5 shown in FIG. 8A.

FIG. 9A is a schematic cross-sectional view illustrating a step of a method of manufacturing an interposer substrate.

FIG. 9B is a schematic cross-sectional view illustrating a step of a method of manufacturing an interposer substrate.

FIG. 9C is a schematic cross-sectional view illustrating a step of a method of manufacturing an interposer substrate.

FIG. 9D is a schematic cross-sectional view illustrating a step of a method of manufacturing an interposer substrate.

FIG. 10 is a plan view schematically showing an electronic device package of an embodiment of the invention.

FIG. 11 is a cross-sectional view taken along the line M6-M6 shown in FIG. 10.

FIG. 12 is a plan view schematically showing an example of a conventional interposer substrate.

FIG. 13 is a cross-sectional view taken along the line M7-M7 shown in FIG. 12.

### DETAILED DESCRIPTION OF THE INVENTION

Hereinafter, preferred embodiments of an interposer substrate of the invention will be described with reference to drawings.

### First Embodiment

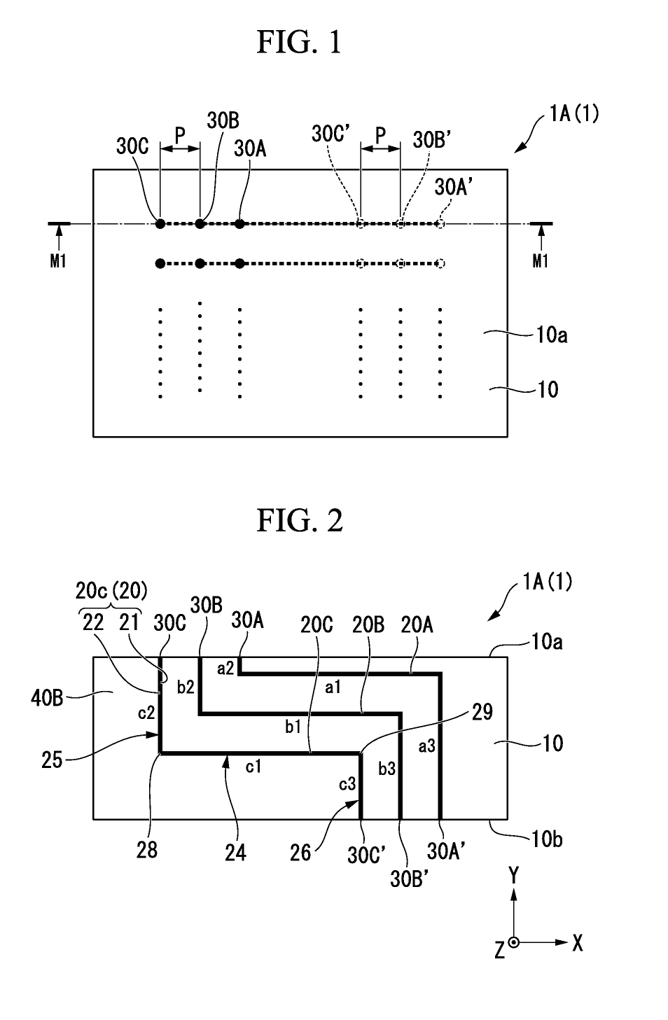

FIGS. 1 to 4 schematically show a configuration example of an interposer substrate of the first embodiment of the invention.

Here, FIG. 1 is a plan view illustrating a state where a plurality of terminal groups are arranged on a top face in the interposer substrate of the first embodiment of the invention.

Additionally, FIG. 2 is a cross-sectional view taken along the line M1-M1 shown in FIG. 1.

An interposer substrate 1A (1) is provided with a plurality of through-hole interconnections 20A, 20B, and 20C (20), which connect main surfaces (the first main surface 10a and the second main surface 10b) constituting a single the substrate 10.

In other words, the through-hole interconnection 20 (20A, 20B, and 20C) has two end portions, a first end portion (one of end portions) of the through-hole interconnection 20 is located on the first main surface 10a, and a second end portion (the other of end portions) of the through-hole interconnection 20 is located on the second main surface 10b.

As a material used to form the substrate 10, an insulator such as glass, plastic, ceramics, or the like, a semiconductor such as silicon (Si) or the like is adopted.

In a case where a semiconductor substrate is used as a material used to form the substrate 10, it is desirable that insulating layers be formed on inner walls, main surfaces, or the like of through holes 21.

In a case where an insulating substrate is used as a material used to form the substrate 10, since insulating layers are not further formed on the inner walls of the through holes 21, it is more preferable.

Conductors 22 are arranged inside the through holes 21 having first exposed portions 30A, 30B, and 30C exposed on one of main surfaces (first main surface) 10a of the substrate 10 and second exposed portions 30A′, 30B′, and 30C′ opened at near the other of main surfaces (second main surface) 10b of the substrate 10.

Through-hole interconnections 20 (20A, 20B, and 20C) are formed by the conductors 22.

The through-hole interconnection 20 is constituted of a first portion 24, a second portion 25, and a third portion 26.

The first portion 24 is formed inside the substrate 10 while extending so that the longitudinal direction of the first portion 24 is substantially parallel to the main surface of the substrate 10.

The second portion 25 and the third portion 26 are positioned at both ends of the first portions 24, respectively.

In other words, the second portion 25 forms a first end portion (one of end portions) of the through-hole interconnection 20, and the third portion 26 forms a second end portion (the other of end portions) of the through-hole interconnection 20.

That is, the end portion (first end portion) of the second portion 25 is located at the first main surface 10a (exposed to space facing the first main surface 10a), and the end portion (second end portion) of the third portion 26 is located at the second main surface 10b (exposed to space facing the second main surface 10b).

The first portion 24 and the second portion 25 are connected at a bend portion 28.

The first portion 24 and the third portion 26 are connected at a bend portion 29.

The configurations of the bend portions 28 and 29 are not particularly limited.

The bend portions may be a configuration having a corner in the vertical cross section thereof.

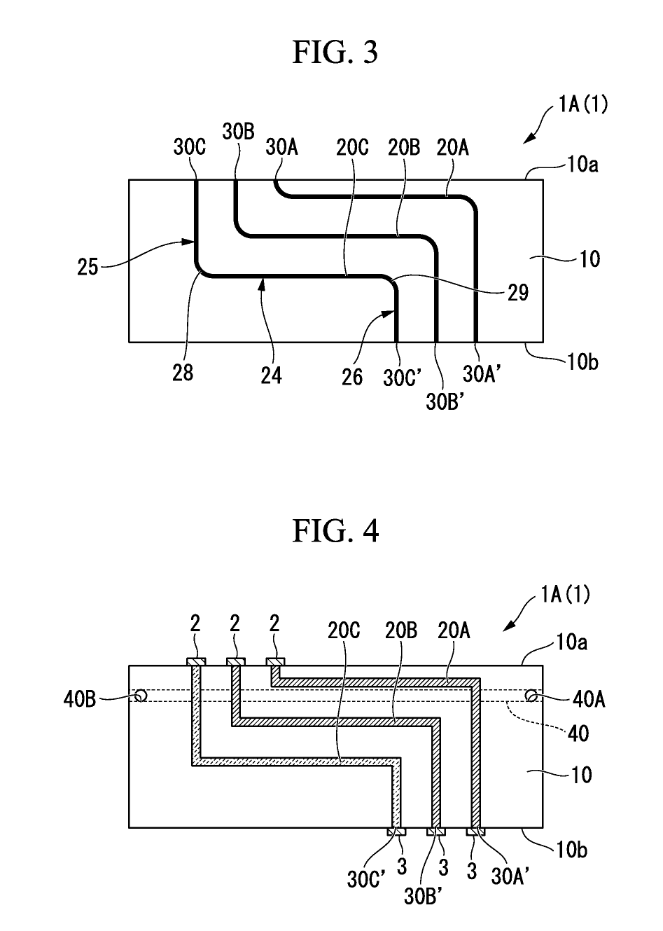

Alternatively, as shown in FIG. 3, a substantially arc shape not having a corner may be used.

In terms of high-speed transmission, a substantially arc-shaped bend portion not having a corner is preferably used.

Moreover, the longitudinal directions of the second portion 25 and the third portion 26 are substantially perpendicular to the main surfaces 10a and 10b, respectively.

The longitudinal direction of the second portion 25 is substantially vertical to the first main surface 10a, and the longitudinal direction of the third portion 26 is substantially vertical to the second main surface 10b.

Because of this, even in cases where the substrate 10 has variations in the initial thickness thereof or variations depending on processing accuracy in a process of polishing a substrate 10 occur, the positions of the exposed portions 21A and 21B provided on the main surfaces of the substrate 10 do not vary.

By means of this structure, it is possible to reliably form the through-hole interconnections 20 with a high level of accuracy.

That is, variations in wiring length do not occur in a plurality of through-hole interconnections.

Even if the thickness of the substrate 10 varies, the interconnection resistances of the through-hole interconnections 20 can be constant while the terminals provided on two surfaces of the main surfaces forming the substrate can be connected to each other.

As the conductors 22 used for the through-hole interconnections 20, conductors can be adopted made of a metal such as copper (Cu), tungsten (W), or the like, alloy such as gold tin (Au—Sn) or the like, non-metal such as polysilicon or the like.

As a method of filling through holes 21 with conductors or a method of forming conductors, a plating method, a sputtering method, a molten metal filling method, a chemical vapor deposition method, a supercritical fluid deposition method, a printing method, and a method in which such methods are combined, or the like can be adequately used.

In particular, as a structure of the through-hole interconnection 20, both a structure in which the inside of the through hole 21 is fully filled with the conductor 22 and a structure in which the inside of the through hole 21 is not fully filled with the conductor 22 are applicable.

When an interposer substrate is used in a package required for airtightness, a structure in which the inside of the through hole 21 is completely filled with the conductor 22 is desirable.

In the interposer substrate 1A (1), a plurality of terminal groups are arranged on the surface thereof.

Terminals arranged on the first main surface 10a of the substrate 10 (the first main surface 10a side) are electrically connected to terminals arranged on another second main surface 10b of the substrate 10 (the second main surface 10b side) through the through-hole interconnections 20, respectively.

For example, as shown in FIGS. 1 and 2, first terminal groups 30A, 30B, and 30C which align at regular intervals are disposed on the first main surface 10a of the substrate 10.

Second terminal groups 30A′, 30B′, and 30C′, whose positions in the second main surface 10b are different from that of the first terminal groups in the X direction, are disposed on the second main surface 10b of the substrate 10 with the same layout as that of the first terminal groups.

Consequently, the first terminal groups 30A, 30B, and 30C are electrically connected to the second terminal groups 30A′, 30B′, and 30C′ through the through-hole interconnections 20A, 20B, and 20C, respectively, so that the terminal numbers thereof correspond to each other.

That is, the first terminal 30A is electrically connected to the second terminal 30A′ through the through-hole interconnection 20A.

Additionally, the first terminal 30B is electrically connected to the second terminal 30B′ through the through-hole interconnection 20B.

Furthermore, the first terminal 30C is electrically connected to the second terminal 30C′ through the through-hole interconnection 20C.

Furthermore, as shown in FIG. 2, in the interposer substrate 1A (1) of the first embodiment of the invention, the overall lengths of the through-hole interconnections 20A, 20B, and 20C (20) are the same as each other.

Specifically, in the through-hole interconnection 20A, where the length of the first portion 24 (portion A) is represented as a1, the length of the second portion 25 (portion B) is represented as a2, and the length of the third portion 26 (portion C) is represented as a3, the length of the through-hole interconnection 20A is represented as (a1+a2+a3).

Similarly, where the length of the first portion 24 is represented as b1, the length of the second portion 25 is represented as b2, and the length of the third portion 26 is represented as b3 in the through-hole interconnection 20B, the length of the through-hole interconnection 20B is represented as (b1+b2+b3).

Moreover, where the length of the first portion 24 is represented as c1, the length of the second portion 25 is represented as c2, and the length of the third portion 26 is represented as c3 in the through-hole interconnection 20C, the length of the through-hole interconnection 20C is represented as (c1+c2+c3).

Therefore, in the interposer substrate 1A (1) of the first embodiment of the invention, relationship (a1+a2+a3)≈(b1+b2+b3)≈(c1+c2+c3) is satisfied.

According to the first embodiment of the invention, the overall lengths of the through-hole interconnections 20A, 20B, and 20C (20) are substantially the same as each other.

For this reason, it is possible to reduce difference (variations) in the resistance values of the through-hole interconnections due to a difference in the lengths of the through-hole interconnections.

As a result, in the interposer substrate 1 of the first embodiment of the invention, it is possible to almost uniformize the electrical resistances of the through-hole interconnections 20A, 20B, and 20C (20).

For this reason, when connection terminals of a mounted device are electrically connected to the through-hole interconnections, respectively, the first embodiment of the invention realizes an interposer substrate which can accurately reflect and transmit signals transmitted from the mounted device and which possesses excellent transmission characteristics.

Particularly, it is essential to not only make the lengths of the through-hole interconnections 20A, 20B, and 20C (20) equal but also make the material of wirings or the thicknesses thereof uniform in order to reduce variations in interconnection resistances inside the substrate.

Additionally, in the interposer substrate 1A (1) of the first embodiment as shown in FIG. 4, pads 2 and 3 may be provided on the main surfaces 10a and 10b of the substrate 10, respectively, so as to electrically connect the second portion 25 and the third portion 26 which constitute the through-hole interconnection 20.

In this case, when devices are mounted on both faces of the interposer substrate 1A (1), electrodes of the devices are electrically connected to the pads without front wirings.

Because of this, the through-hole interconnections 20 can be directly connected to the devices, even in cases where a downsized device in which the electrodes are densely arranged with any layout is used, it is possible to easily connect the downsized device to the interposer substrate.

Additionally, in the interposer substrate 1A (1), the substrate 10 may include a cooling unit cooling the substrate 10.

As such cooling unit cooling the substrate 10, for example, a flow passage 40 allowing a cooling fluid to flow therein is adopted as shown in FIG. 4.

By means of this structure, even in cases where a device having a large amount of heat generation is mounted onto the interposer substrate, an increase in temperature of the entire package can be reduced by applying a cooling medium to the flow passage 40.

The flow passage 40 includes outlet-inlet ports 40A and 40B which are provided at both ends of the flow passage 40 and which discharge and supply the cooling fluid.

For example, a plurality of flow passages 40 may be provided.

Furthermore, the flow passage 40 may be provided so as to wind its way so that single flow passage 40 can cool over the entirety of the substrate 10.

In addition, a constitution in which the outlet-inlet ports 40A and 40B of the flow passage 40 are exposed on a main surface of the substrate 10 may be used.

Moreover, the pattern (pathway) or the cross-sectional shape of the flow passage 40 is not limited to the aforementioned structure and can be appropriately designed.

However, it is preferable that the flow passage 40 itself maintain a predetermined distance from the through hole 21 in a direction three-dimensionally parallel to the a surface or a thickness direction so as not to communicate with the through hole having the through-hole interconnection 20.

The flow passage 40 can be formed by the same method as the method of providing the through holes 21 used for forming the through-hole interconnections 20 therein.

At this time, when the through holes 21 used for forming the through-hole interconnections 20 are formed, a through hole serving as the flow passage 40 is preferably formed collaterally and simultaneously.

By simultaneously forming the through holes 21 of the through-hole interconnections 20 and the through hole used as the flow passage 40, a manufacturing process therefor can be simplified and the cost therefor can be reduced.

In addition, positional relationships between the through holes 21 and the flow passage 40 can be easily controlled, and a defect such that the through holes 21 and the flow passage 40 are incorrectly communicated with each other can be avoided.

### Modified Example of First Embodiment

In the aforementioned embodiment, the structure in which the longitudinal directions of the first portions of the through-hole interconnections 20 are substantially parallel to a main surface of the substrate is illustrated as an example.

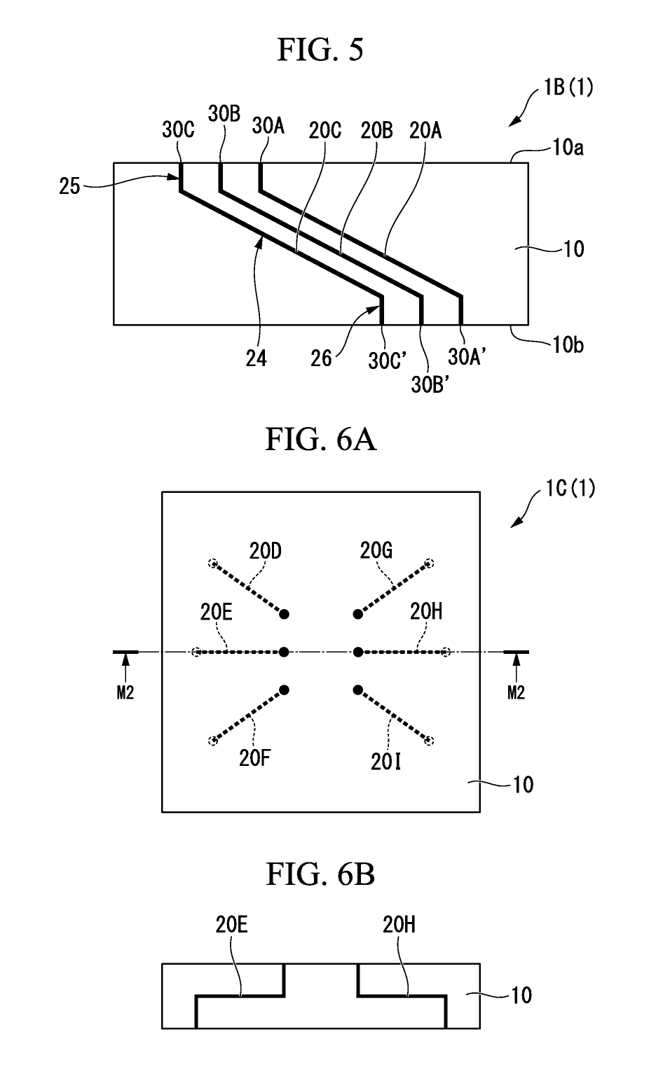

In a modified example of the first embodiment of the invention, as shown in FIG. 5, the invention is applicable to the case where the longitudinal directions of first portions of the through-hole interconnections 20 are oblique to a main surface of the substrate 10.

By forming the first portions at an angle to the main surface of the substrate 10, it is possible to shorten the overall length of each of the through-hole interconnections 20 connecting two main surfaces 10a and 10b of the substrate 10, and the interconnection resistances can be reduced.

### Second Embodiment

Additionally, in a second embodiment of the invention, arrangement of a plurality of through-hole interconnections 20 inside the substrate 10 is not particularly limited, and various arrangements can be adopted.

For example, FIG. 6A is a plan view schematically showing an example of an interposer substrate 1C (1), and FIG. 6B is a cross-sectional view taken along the line M2-M2 shown in FIG. 6A.

The interposer substrate 1C (1) includes a plurality of through-hole interconnections 20D to 20I, and the through-hole interconnections 20D to 20I are radially arranged as seen from a vertical direction of the interposer substrate.

### Third Embodiment

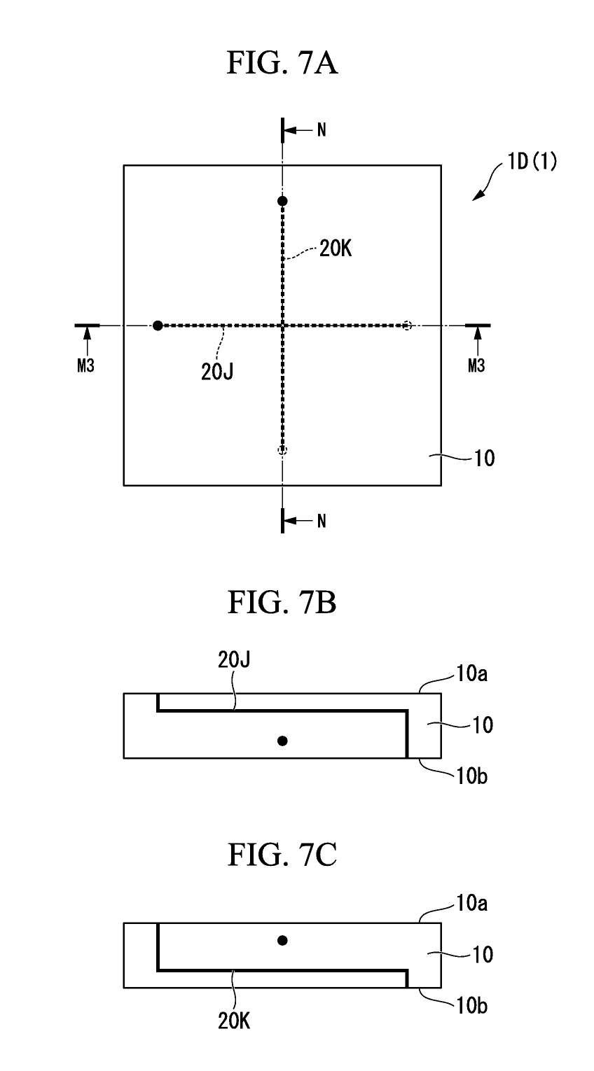

Additionally, in a third embodiment of the invention, FIG. 7A is a plan view schematically showing an example of an interposer substrate 1D (1), FIG. 7B is a cross-sectional view taken along the line M3-M3 shown in FIG. 7A, and FIG. 7C is a cross-sectional view taken along the line N-N shown in FIG. 7A.

The interposer substrate 1D (1) includes through-hole interconnections 20J and 20K which are arranged substantially orthogonal to each other as seen from a vertical direction of the interposer substrate.

### Fourth Embodiment

In the aforementioned embodiments, the structure in which the through-hole interconnections 20 are arranged so as to connect two main surfaces 10a and 10b located opposite to each other in the substrate 10 is illustrated as an example, but the invention is not limited to this.

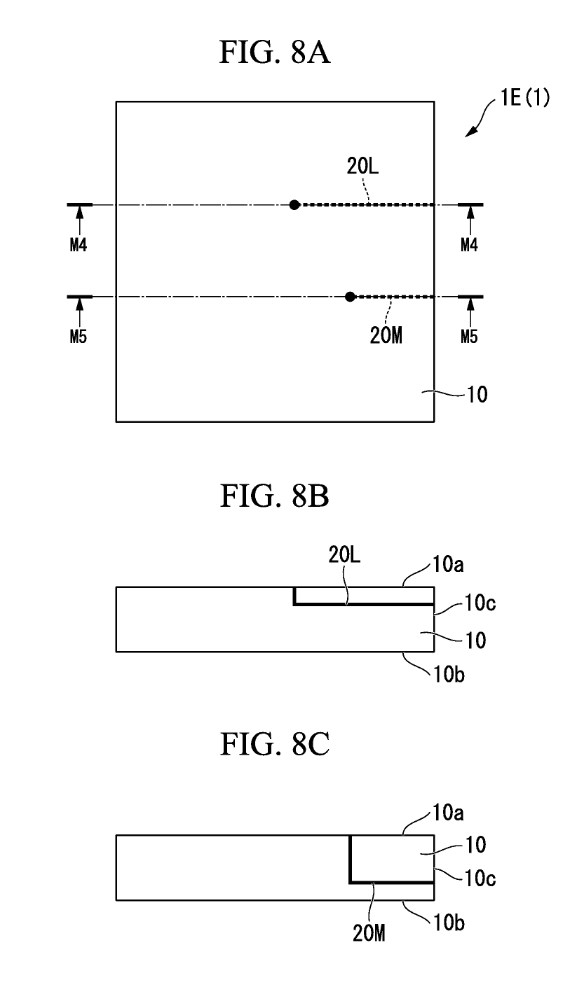

In a fourth embodiment of the invention, FIG. 8A is a plan view schematically showing an example of an interposer substrate 1E (1), FIG. 8B is a cross-sectional view taken along the line M4-M4 shown in FIG. 8A, and FIG. 8C is a cross-sectional view taken along the line M5-M5 shown in FIG. 8A.

In the interposer substrate 1E (1), the through-hole interconnections 20L and 20M are arranged so as to connect a terminal which is provided on the main surface 10a of the substrate to a terminal which is provided on a main surface 10c, and the main surface 10c is substantially vertical to the main surface 10a and is parallel to the thickness direction of the substrate 10.

In this case, the lengths of the through-hole interconnections 20L and 20M are also substantially equal to each other.

### Method Of Manufacturing Interposer Substrate

Next, a method of manufacturing the above-described interposer substrate 1A (1) will be described.

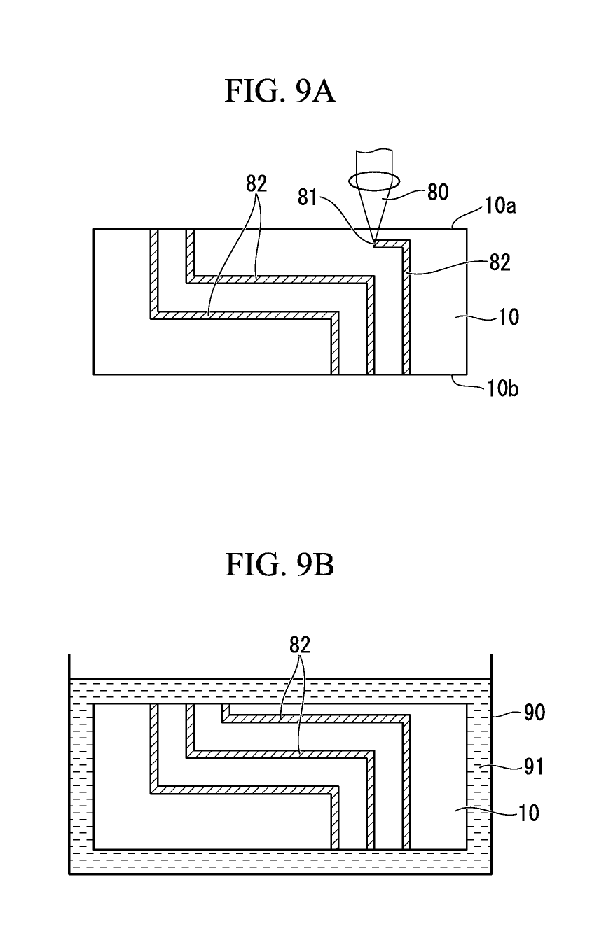

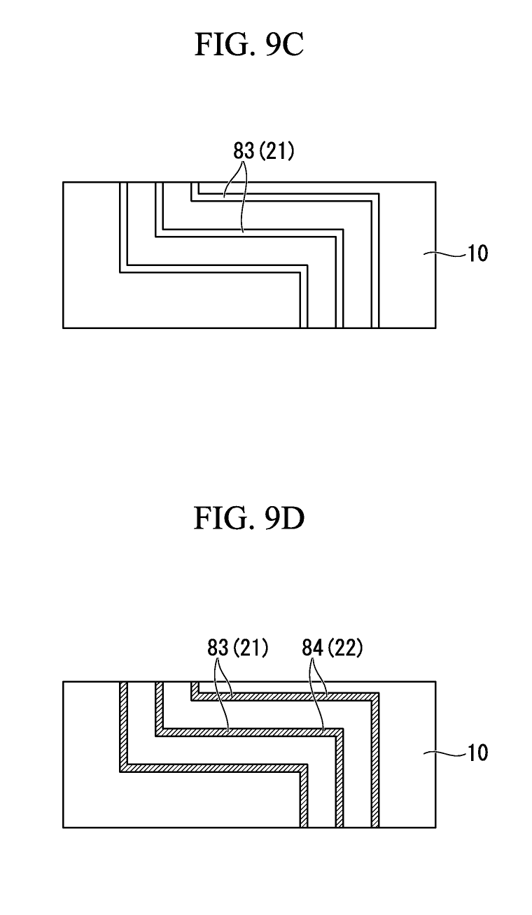

FIGS. 9A to 9D are cross-sectional views schematically showing a manufacturing method of the interposer substrate 1A (1) in the order of steps thereof.

In the embodiment, as a base material, a glass substrate (silica) having a thickness of 500 μm is used.

In addition, a manufacturing method of a microscopic hole in the embodiment modifies part of a silica substrate using a laser, thereafter, remove the modified portion by etching.

Firstly, as shown in FIG. 9A, modified regions 82 are formed inside the substrate 10 by irradiating, with a laser light 80, the portion on the substrate 10 made of silica, on which at least microscopic hole are to be formed in a subsequent step.

In the embodiment, a femtosecond laser is used as a light source of the laser light 80, the inside of the substrate 10 is irradiated with laser beam so that a focal point 81 is focused therein, and modified regions are obtained which have a diameter of, for example, several μm to dozens of μm.

At this time, it is possible to form modified regions 82 having various configurations by controlling the focal point 81 and the substrate position.

In other cases, the substrate 10, in which microscopic holes are to be formed, is not limited to a silica substrate, and as the substrate, for example, an insulative substrate 10 such as sapphire or the like or a glass substrate having other components containing an alkaline component or the like may be used.

Also, the thickness of the glass substrate is set to appropriately in the range of approximately 150 μm to 1 mm.

Subsequently, as shown in FIG. 9B, the substrate 10 in which the modified regions 82 are formed is immersed in a predetermined chemical solution 91 contained in a container 90.

Consequently, the modified regions 82 are wet-etched by the chemical solution and are removed from the inside of the substrate 10.

As a result, as shown in FIG. 9C, the microscopic hole 83 (the through hole 21) is formed at the portion at which the modified region 82 was present before.

In the embodiment, as the chemical solution, an acid solution containing hydrofluoric acid as a main component is used.

The etching used in this embodiment utilizes a phenomenon that the modified region 82 is etched extremely faster than non-modified portion, it is possible to finally form a microscopic hole 83 having the configuration which is caused by the modified region 82.

In the embodiment, the hole diameter of the microscopic hole 83 is 50 μm.

In other cases, the chemical solution is not limited to hydrofluoric acid. For example, a mixed acid or the like containing hydrofluoric-nitric acid system in which an appropriate amount of nitric acid or the like is added into hydrofluoric acid, or an alkaline solution or the like such as potassium hydroxide solution can be used.

Furthermore, the hole diameter of the microscopic hole can be appropriately determined as long as it is in the range of approximately 10 to 300 μm depending on the intended use of the through-hole interconnection.

Moreover, the microscopic hole 83 formed by the aforementioned method is not limited to a “through hole” penetrating through the substrate 10 and may be a “blind hole” not penetrating through the substrate.

According to the aforementioned method, it is possible to form microscopic holes 83 having a three-dimensional free structure in the silica substrate 10.

After that, as shown in FIG. 9D, the insides of the microscopic holes 83 are filled with electroconductive substance 84 (conductors 22).

In the embodiment, gold tin (Au—Sn) is used as the electroconductive substance 84 (conductors 22), and the insides of the microscopic holes are filled with that by a molten metal filling method.

The molten metal filling method is a method which can fill the insides of the microscopic holes with that by action of a pressure difference with a high level of airtightness in a short amount of time.

Additionally, gold tin (Au—Sn) is used as a metal filler in the embodiment, it is not limited thereto.

A metal such as gold-tin alloy containing different compositions, tin (Sn), indium (In), or the like, or a solder such as a tin lead (Sn—Pb) based solder, a tin (Sn) based solder, a lead (Pb) based solder, a gold (Au) based solder, an indium (In) based solder, an aluminum (Al) based solder, or the like, may be used.

Additionally, a molten metal suction method is used as a filling method in the above description, but it is not limited to this method, a plating method, a sputtering method, a chemical vapor deposition method, a supercritical fluid deposition method, a printing method, and a method in which such methods are combined can be adequately used.

Furthermore, the conductors which are to be filled or formed are not limited to (Au—Sn), Cu, W, polysilicon, electroconductive paste, carbon nanotubes, or the like can be adequately used.

It is possible to provide the interposer substrate 1A (1) including a plurality of the through-hole interconnections 20 by the above-described method.

In addition, the structure in which the microscopic holes 83 penetrate through the substrate 10 is adopted in the above-described embodiment, but the invention is not limited to this structure.

For example, blind holes 83 are preliminarily formed on the substrate 10, the microscopic holes are filled with metal, thereafter, the through-hole interconnections 20 can also be formed by polishing the substrate 10.

In the case of polishing the substrate 10 as stated above, since the longitudinal directions of the second portions and the third portions in the through-hole interconnections 20 in the embodiment are substantially perpendicular to the main surface, variations in the interconnection resistances of the through-hole interconnections 20 do not occur even if the main surface of the substrate 10 is polished.

Additionally, the structure in which the substrate 10 is modified by directly irradiating the inside of the substrate with a laser is illustrated as an example in the aforementioned embodiment, it is not limited to this, the substrate 10 may be modified by use of, for example, a hologram technique.

### Electronic Device Package

Next, an electronic device package using the interposer substrate 1A (1) the above-described invention will be described.

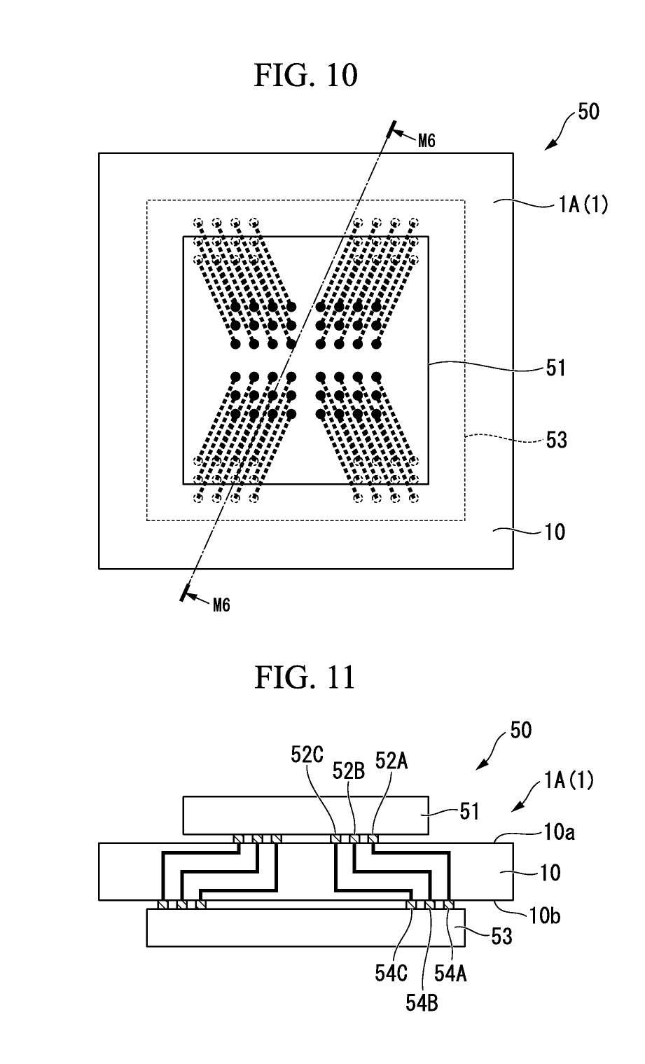

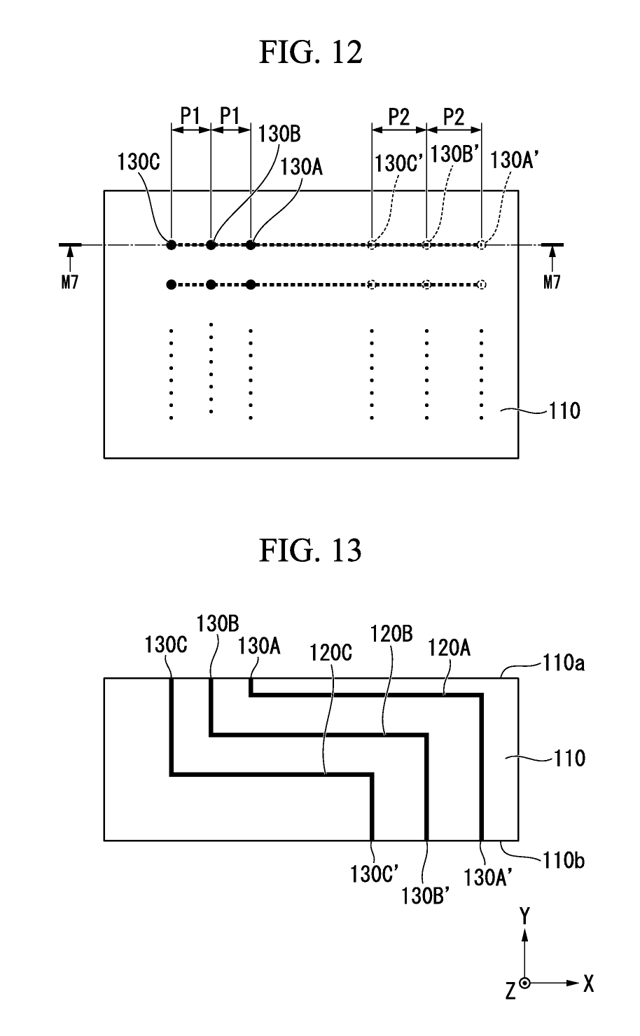

FIG. 10 is a plan view schematically showing an embodiment (configuration example) of an electronic device package related to the invention.

Additionally, FIG. 11 is a cross-sectional view taken along the line M6-M6 shown in FIG. 10.

In the electronic device package 50, an electronic device is mounted onto at least one of main surfaces of the interposer substrate 1.

As described above, since the overall lengths of the through-hole interconnections 20A, 20B, and 20C (20) are substantially the same as each other in the interposer substrate 1, it is possible to reduce difference (variations) in the resistance values of the through-hole interconnections due to a difference in the lengths of the through-hole interconnections.

Therefore, in the electronic device package 50, the electrical resistances of the through-hole interconnections 20A, 20B, and 20C (20) provided in the interposer substrate 1 are substantially uniform to each other.

Because of this, according to the invention, an electronic device package with excellent transmission characteristics is obtained.

The electronic device package 50 is provided with the interposer substrate 1 having the through-hole interconnections 20 in which the through holes 21 formed on the substrate 10 is filled or formed with the conductors 22; a first device 51 disposed on the first main surface 10a of the substrate 10; and a second device 53 disposed on the second main surface 10b of the substrate 10.

The arrangement of electrodes of the first device 51 and the arrangement of electrodes of the second device 53 are different from each other.

By use of the interposer substrate 1, electrodes 52A, 52B, and 52C of the first device 51 disposed on the first main surface 10a of the substrate 10 and electrodes 54A, 54B, and 54C of the second device 53 disposed on the second main surface 10b of the substrate 10 are electrically connected, respectively, with the through-hole interconnections 20A, 20B, and 20C interposed therebetween.

An integrated circuit (IC) such as a memory (storage element), a logic (logical element), or the like, a MEMS device such as a sensor or the like, an optical device such as a light-emitting element, a light receiving element, or the like is adopted as the devices 51 and 53.

As long as the arrangement of electrodes of the devices 51 and 53 are different from each other, the functions of the devices 51 and 53 may be different from each other or the same as each other.

Particularly, it is possible to realize three-dimensional system in package (SiP) by high-densely integrating different kinds of devices thereinto.

Furthermore, as shown in FIG. 11, in the electronic device package 50, at least one of the exposed end portion of the second portion 25 and the end portion of the third portion 26 is disposed at a position facing the electrodes 52 and 54 of the devices 51 and 53 which are to be mounted.

It is preferable that the electrodes of the devices 51 and 53 be electrically connected to at least one of the end portion of the second portion 25 and the end portion of the third portion 26.

As a result, even in cases where a downsized device in which the electrodes are densely arranged with any layout is used, since the electrodes 52 (52A, 52B, 52C) of the device 51 and the electrode 54 (54A, 54B, 54C) of the device 53, which are mounted onto both faces of the interposer substrate 1, are electrically connected to each other without front wirings, it is possible to freely connect the electrodes 52 and the electrodes 54.

### Electronic Component

An electronic component related to the invention is provided with at least the above-described the electronic device package 50 of the invention.

For this reason, the invention can realize an electronic device with excellent transmission characteristics.

In the above-description, the interposer substrate, the electronic device package, and the electronic component of the invention are described, the technical scope of the invention is not limited to the above embodiments, and various modifications may be made without departing from the scope of the invention.

### INDUSTRIAL APPLICABILITY

The invention is widely applicable to an interposer substrate including through-hole interconnections, and an electronic device package using this, and an electronic component.

What is claimed is:

1. An interposer substrate comprising:
a single substrate having a first main surface and a second main surface;
a plurality of through-hole interconnections having at least a first portion formed so as to extend in a direction different from a thickness direction of the substrate, a second portion constituting one of end portions of a through-hole interconnection, and a third portion constituting the other of the end portions of the through-hole interconnection, the through-hole interconnections being provided inside the substrate so as to connect the first main surface to the second main surface, wherein
the second portion is substantially perpendicular to the first main surface and is exposed to the first main surface,
the third portion is substantially perpendicular to the second main surface and is exposed to the second main surface, and
lengths of the through-hole interconnections are the same as each other.

2. The interposer substrate according to claim 1, wherein
a longitudinal direction of the first portion is substantially parallel to a main surface of the substrate.

3. The interposer substrate according to claim 1, wherein
a longitudinal direction of the first portion is oblique to a main surface of the substrate.

4. The interposer substrate according to claim 1, further comprising:
a pad provided on the first main surface so as to be electrically connected to the second portion constituting the through-hole interconnection; and
a pad provided on the second main surface so as to be electrically connected to the third portion constituting the through-hole interconnection.

5. The interposer substrate according to claim 1, wherein
the substrate comprises a cooling unit cooling the substrate.

6. An electronic device package comprising:
the interposer substrate according to claim 1; and
an electronic device mounted onto at least one of the first main surface and the second main surface of the interposer substrate.

7. The electronic device package according to claim 6, wherein
at least one of an end portion of the second portion and an end portion of the third portion is located at a position facing a terminal of the electronic device and is electrically connected to the terminal of the electronic device.

8. An electronic component comprising the electronic device package according to claim 6.
